(19) United States
(12) Patent Application Publication
(10) Pub. No.: US 2010/0161262 A1
(43) Pub. Date: Jun. 24, 2010

(54) Method for Calculating Capacitance of High Voltage Depletion Capacitor

(76) Inventor: Sang Hun Kwak, Seoul (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/631,746

(22) Filed: Dec. 4, 2009

(30) Foreign Application Priority Data
Dec. 24, 2008 (KR) 10-2008-0132819

(51) Int. Cl. G01R 27/00; G01R 27/26

(52) U.S. Cl. 702/65; 324/686

(57) ABSTRACT

A method for calculating a capacitance of a high voltage depletion capacitor is disclosed. The method includes measuring capacitance values of a high voltage depletion capacitor according to an applied voltage, storing measured capacitance values in a data storage device, setting a polynomial-type mathematical model including a plurality of parameters based on the measured capacitance values, calculating parameter coefficients using the measured capacitance values and the polynomial-type mathematical model, and calculating the capacitance of the high voltage depletion capacitor using the polynomial-type mathematical model and the calculated parameter coefficients.

### CROSS REFERENCE TO RELATED APPLICATION

This application claims the benefit of Korean Patent Application No. 10-2008-0132819, filed on Dec. 24, 2008, which is hereby incorporated by reference as if fully set forth herein.

### BACKGROUND OF THE DISCLOSURE

1. Field of the Disclosure

The present invention relates to a method for calculating capacitance, and more particularly, to a method for calculating capacitance of a high voltage depletion capacitor.

2. Discussion of the Related Art

A frequency synthesizing apparatus having a phase locked loop is typically used in a wireless receiver, and a Voltage Controlled Oscillator (VCO) is an important device for manufacturing the frequency synthesizing apparatus. Here, an important parameter of VCO is a varactor that determines a frequency tuning range of VCO.

In general, such a varactor (also referenced as a “Variable Capacitor” or “Voltage-Variable Capacitor”) is a semiconductor device that is able to control or vary an electrical capacity (e.g., capacitance) according to a size of an applied voltage.

FIG. 1 is a diagram illustrating a structure of a conventional MOS varactor. FIG. 2 is a graph illustrating a capacitance characteristic as a function of the gate voltage of the conventional MOS varactor shown in FIG. 1.

In reference to FIGS. 1 and 2, the conventional MOS varactor is a MOSCAP type, and it includes an N-type well 120 formed in a substrate 110, a N+-type source/drain 130, a gate oxide layer 135 formed on the substrate 110, a gate poly 140 and P+-type region 145. If a gate voltage (Vgate=VCC) is applied to the gate poly 140, the capacitance of the MOS varactor is determined by the quantity of electric charge according to voltages (VSS and VCC) applied to the N-type well 120 and the gate poly 140.

In an LCD driver IC (LDI) manufacturing process, a high voltage depletion capacitor is used. Although the structure of such a high voltage depletion capacitor may be similar to the structure of the conventional MOS varactor, a different characteristic is generated because of a different condition of the N-type well. As a result, there have been increasing demands for a new model and method for estimating or calculating the capacitance characteristics of the high voltage depletion capacitor (e.g., such the gate voltage).

### SUMMARY OF THE DISCLOSURE

Accordingly, the present invention is directed to a method for calculating a capacitance of a high voltage depletion capacitor.

An object of the present invention is to provide a modeling method applicable to a capacitance characteristic of a high voltage depletion capacitor with respect to an applied voltage (e.g., a gate voltage).

Additional advantages, objects, and features of the disclosure will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose of the invention, as embodied and broadly described herein, a method for calculating a capacitance of a high voltage depletion capacitor may include measuring capacitance values of a capacitor (e.g., a high voltage depletion capacitor having a MOS varactor structure) according to an applied voltage (e.g., applied to the upper electrode of the capacitor, or gate of the MOS varactor); storing the measured capacitance values in a data storage device; setting a polynomial-type mathematical model including a plurality of parameters based on the stored capacitance values; calculating parameter coefficients using the measured capacitance values and the polynomial-type mathematical model; and calculating a capacitance of the capacitor using the polynomial-type mathematical model and the calculated parameter coefficients. The capacitor for which capacitance values are measured may be a manufactured high voltage depletion capacitor, and the capacitor for which capacitance values are calculated may be a high voltage depletion capacitor that is not yet manufactured (e.g., a “simulated” high voltage depletion capacitor).

It is to be understood that both the foregoing general description and the following detailed description of the present invention are exemplary and explanatory and are intended to provide further explanation of the invention as claimed.

According to the method for calculating the capacitance of the high voltage depletion capacitor according to exemplary embodiments of the present invention, a polynomial-type mathematical model applicable to a high voltage depletion capacitor is provided only to calculate a precise capacitance and to enable precise simulation when designing.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle(s) of the disclosure. In the drawings:

FIG. 1 is a diagram illustrating a structure of a conventional MOS varactor;

FIG. 2 is a graph illustrating a capacitance characteristic for the conventional MOS varactor shown in FIG. 1 as a function of the gate voltage;

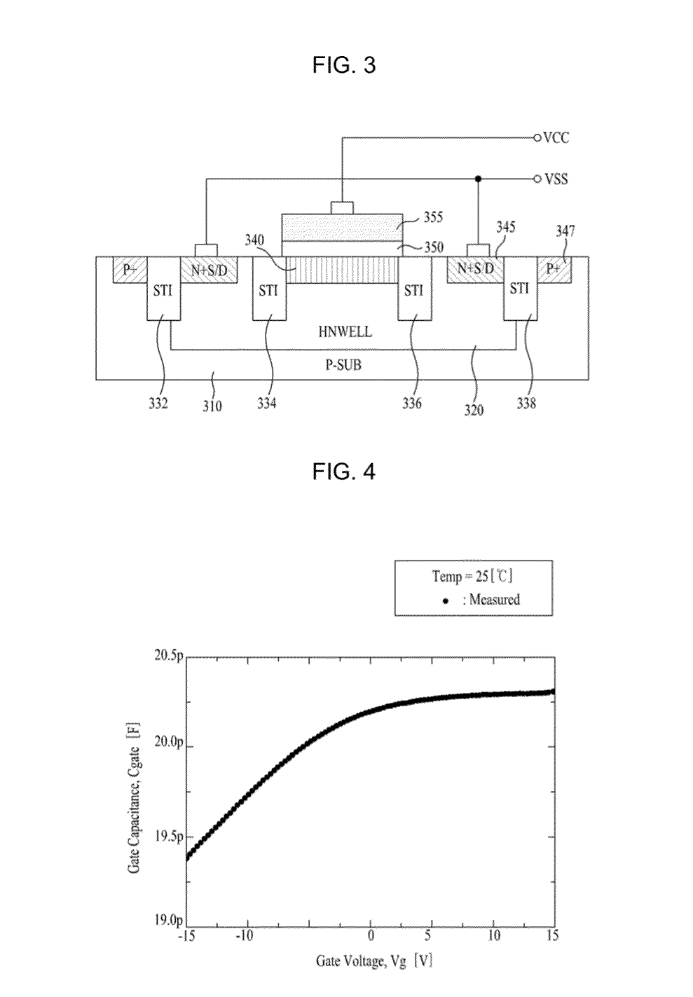

FIG. 3 is a cross-sectional view illustrating a high voltage depletion capacitor to which a modeling method according to exemplary embodiments of the present invention is applied;

FIG. 4 is a graph illustrating a capacitance characteristic according to the gate voltage of the high voltage depletion capacitor shown in FIG. 3;

FIG. 5 is a flow chart illustrating a method for modeling the capacitance as a function of the gate voltage of the high voltage depletion capacitor shown in FIG. 3;

FIG. 6 is a graph illustrating a parameter extracted using an optimized program; and

FIG. 7 is a graph illustrating a capacitance of a high voltage depletion capacitor that is calculated using a mathematical model and the extracted parameter.

### DETAILED DESCRIPTION

Reference will now be made in detail to embodiments of the present invention, examples of which are illustrated in the accompanying drawings. Wherever possible, the same reference numbers will be used throughout the drawings to refer to the same or like parts.

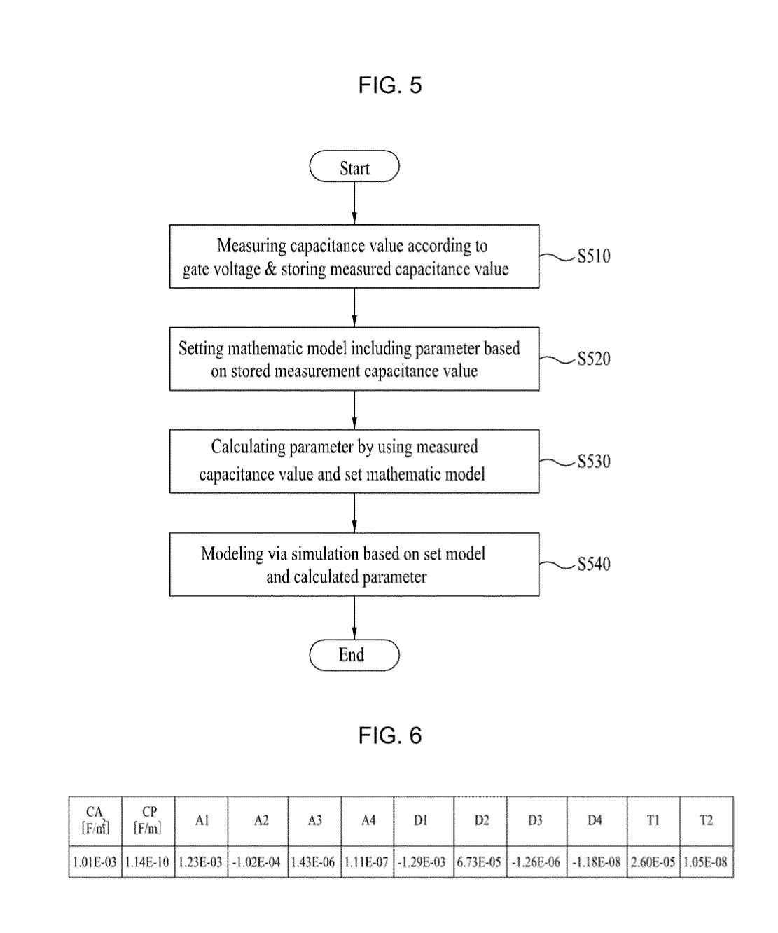

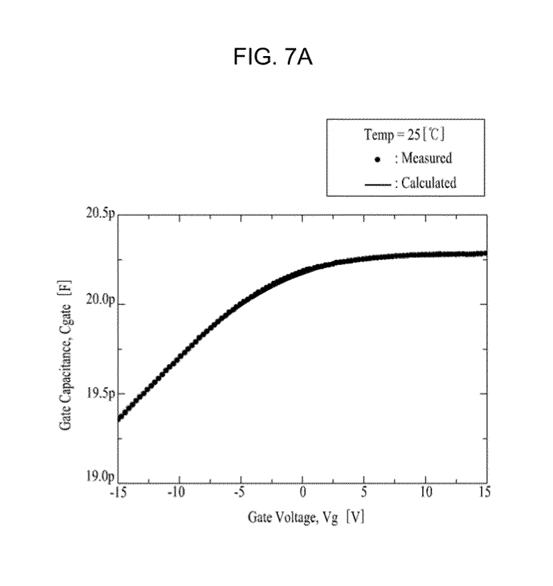

FIG. 3 is a cross-sectional view illustrating a high voltage depletion capacitor 300 having a modeling method according to exemplary embodiments of the present invention applied thereto. FIG. 4 is a graph illustrating a capacitor characteristic according to the gate voltage of the high voltage depletion capacitor 300 shown in FIG. 3.

In reference to FIGS. 3 and 4, the high voltage depletion capacitor 300 includes a substrate 310, a first conductivity-type well (for example, an N-type well) 320, isolation layers 332, 334, 336 and 338, a first doped region 340 having the first conductivity type, a source/drain region 345, a second doped region 347 having a second conductivity type, a gate oxide layer 350 and a gate poly layer 355. The gate poly layer 355 generally comprises polycrystalline silicon (polysilicon, or “poly”) and functions as an upper electrode of the capacitor. The polysilicon and may be replaced with a metal, a metal silicide, or a polysilicon/metal silicide bilayer. However, such material changes may result in changes to the mathematical model (e.g., addition or deletion of one or more parameters and/or changes to one or more parameter values).

In the high voltage depletion capacitor 300, the first conductivity-type well 320 is formed in the substrate 310, and the gate poly 355 is formed on a gate oxide layer 350, in turn formed on the first doped region 340 in the first conductivity-type well 320. The source/drain regions 345 have the first conductivity type and are formed in the first conductivity-type well 320. The first doped region 340 is formed on or in a surface of the first conductivity-type well 320. The isolation layers 332, 334, 336 and 338 isolate the source/drain region 345 from the first conductivity-type doped region 340 and/or the gate poly layer 355 from the well 320. Here, the high voltage depletion capacitor may have a MOS varactor structure.

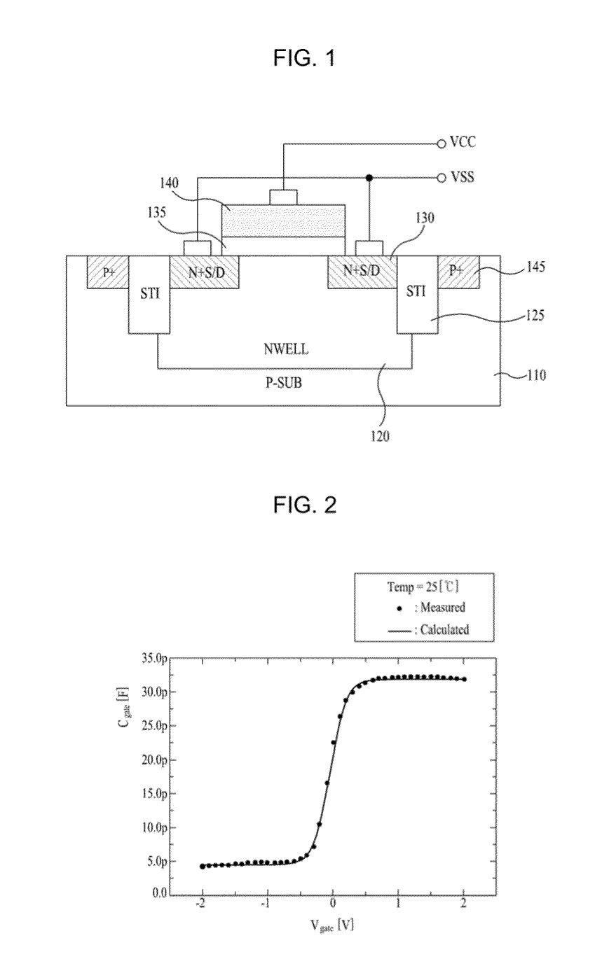

The high voltage depletion capacitor 300 has a similar structure to the structure of the conventional MOS varactor shown in FIG. 1, except the high density N-type doped region 340 is surrounded by the isolation layers 334 and 336 in the surface of the N-type well 320. In various embodiments, the isolation layers 334 and 336 form a ring around the high density N-type doped region 340, and/or the isolation layers 332 and 338 form a ring around the N-type well 320. Such process difference(s) may generate totally different capacitance characteristics, as shown in FIG. 4.

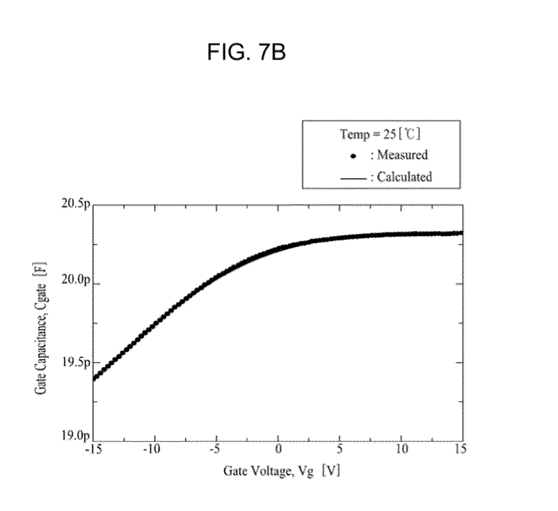

FIG. 5 is a flow chart illustrating a method for modeling the capacitance characteristic as a function of the gate voltage of the high voltage depletion capacitor shown in FIG. 3.

First of all, different gate voltages are applied to the gate (i.e., the upper electrode) of the high voltage depletion capacitor 300, sequentially or otherwise. Capacitance values of the high voltage depletion capacitor 300 according to the applied gate voltages may be measured with a measuring device such as a CV meter, and measured capacitance values are stored in a data storage device (S510). That is, different gate voltages (Vg) are applied to the gate poly 355 of the high voltage depletion capacitor 300 using the measuring device, and a capacitance value between the gate poly 355 and the N-type well 320 according to each gate voltage (Vg) is measured.

For example, the gate voltage (Vg) may be from about −15V to about 15V. In one embodiment, the gate voltage (Vg) applied to the gate poly 355 gradually increases from −15V to 15V by a predetermined value (e.g., 0.1V). The indicators ‘’ shown in FIG. 4 reference a capacitance measurement value (Cgate) for each of the applied gate voltages. The capacitance values measured as mentioned above are stored in the data storage device connected to the measuring device, for example, RAM, flash memory or hard disk of a computer.

A mathematical model including a plurality of parameters is set or determined, based on the capacitance measurement values stored in the data storage device (S520). Various kinds of mathematical models may be based on the capacitance values, and the mathematical model according to exemplary embodiments of the present invention may include a biquadratic polynomial for the applied gate voltages (dV) and a quadratic polynomial for the chip temperature (T).

For example, the mathematical model may include a biquadratic polynomial for the applied gate voltages (dV) and a quadratic polynomial for the chip temperature (T) as shown in Mathematical Equations 1 to 3.

Cg=C1+C2 EQUATION 1:

C1=CA·Area×[1+A1·dV+A2·(dV)²+A3·(dV)³+4·(dV)⁴]×[1+T1·(T−Tn)+T2·(T−Tn)²] EQUATION 2:

C2=CP·Peri×[1+P1·dV+P2·(dV)²+P3·(dV)³+P4·(dV)⁴]×[1+T1·(T−Tn)+T2·(T−Tn)²] EQUATION 3:

Here, ‘C1’ refers to a capacitance element for the area of the gate poly, and ‘C2’ refers to a capacitance element for the length or perimeter of the gate poly. ‘CA’ refers to capacitance per unit area and ‘CP’ refers to capacitance per unit length. ‘Area’ refers to the area of the gate poly and ‘Peri’ refers to the length or perimeter of the gate poly. ‘dV’ refers to the applied gate voltage and ‘T’ refers to the temperature of the capacitor. ‘Tn’ refers to an ambient temperature of the capacitor, for example, 25° C. ‘A1˜A4’ and ‘P1˜P4’ refer to parameter coefficients, determined empirically and/or by the capacitance measurements described herein.

A polynomial-type mathematical model including various parameters may be settable based on the measured capacitance values. Mathematical models disclosed in Mathematical Equations 1 to 3 are set with respect to the high voltage depletion capacitor 300 shown in FIG. 3.

Hence, the parameter coefficients (A1˜A4 and P1˜P4) are calculated using the measured capacitance values (Cgate) and the mathematical model Cg (S530).

For example, the parameter coefficients (A1˜A4 and P1˜P4) may be calculated by using a tool such as origin (e.g., a computer or work station equipped with software for modeling structures in an integrated circuit).

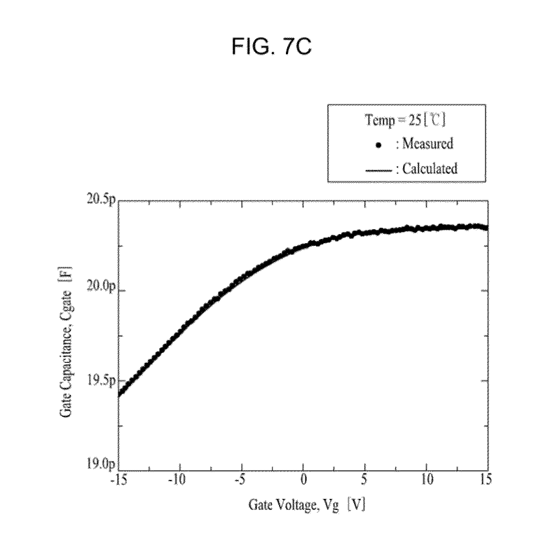

FIG. 6 is a diagram illustrating the parameter coefficients calculated by using the optimizing program.

Hence, the capacitance of the high voltage depletion capacitor 300 as a function of the gate voltage may be calculated using the mathematical model and the parameter coefficients.

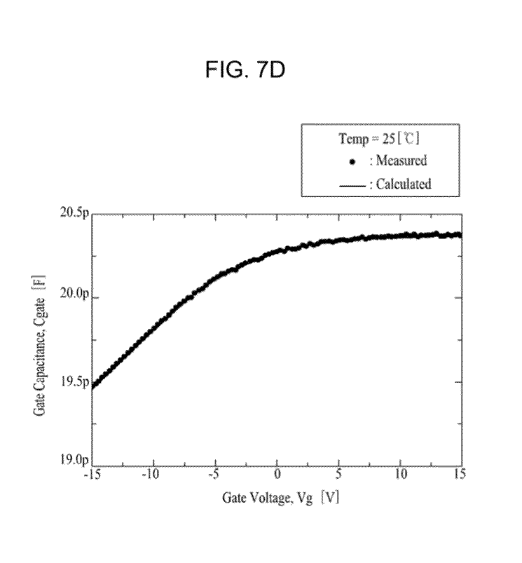

FIGS. 7A to 7D are graphs illustrating the capacitance of the high voltage depletion capacitor 300, calculated using the mathematical model and the parameter coefficients.

In reference to FIGS. 7A to 7D, the graph has a similar profile to the graph of the capacitance of the high voltage depletion capacitor shown in FIG. 4, with a little difference of the chip temperature.

A system including the capacitance of the high voltage depletion capacitor 300 may be simulated using the mathematical models and the parameter coefficients (S540).

For example, the models and the parameter coefficients are supplied to an HSPICE simulator, and the system including the high voltage depletion capacitor 300 is simulated.

Therefore, the invention may further relate to a computer program or computer-readable medium containing a set of instructions which, when executed by an appropriate processing device (e.g., a signal processing device, such as a microcontroller, microprocessor or DSP device, which may reside in a computer or other computing equipment such as a work station), is configured to perform one or more steps of the above-described method.

For example, the computer program may be on any kind of readable medium, and the computer-readable medium may comprise any medium that can be read by a processing device configured to read the medium and execute code stored thereon or therein, such as a floppy disk, CD-ROM, magnetic tape or hard disk drive. Such code may comprise object code, source code and/or binary code.

The code for implementing the present method is generally digital, and is generally configured for processing by a conventional digital data processor (e.g., a microprocessor, microcontroller, or logic circuit such as a programmable gate array, programmable logic circuit and/or device, or application-specific [integrated] circuit).

In an exemplary embodiment, the present invention relates to a computer program or computer-readable medium containing a set of instructions which, when executed by a processing device configured to execute computer-readable instructions, is configured to calculate a capacitance and/or parameter coefficients of a capacitor as a function of applied voltage, as generally described herein.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for calculating a capacitance, comprising:
measuring capacitance values of a capacitor according to an applied voltage, and storing the measured capacitance values in a data storage device;
setting a polynomial-type mathematical model including a plurality of parameters based on the measured capacitance values stored in the data storage device;
calculating parameter coefficients using the measured capacitance values and the polynomial-type mathematical model; and
calculating a capacitance of the capacitor using the polynomial-type mathematical model and the calculated parameter coefficients.

2. The method of claim 1, wherein the capacitance of a high voltage depletion capacitor is calculated.

3. The method of claim 2, wherein the high voltage depletion capacitor has a MOS varactor structure.

4. The method of claim 2, wherein the high voltage depletion capacitor has a first conductivity-type well, a gate on the first conductivity-type well, a gate oxide layer between the gate and the first conductivity-type well, a source/drain region having a first conductivity type in the first conductivity-type well, a doped region having a first conductivity type in a surface of the first conductivity-type well under the gate oxide layer, and isolation layers separating the source/drain region and the doped region.

5. The method of claim 1, wherein the mathematical model comprises a biquadratic polynomial with respect to the applied voltage.

6. The method of claim 5, wherein the biquadratic polynomial comprises the formula:
A1·dV+A2·(dV)²+A3·(dV)³+A4·(dV)⁴
or
P1·dV+P2·(dV)²+P3·(dV)³+P4·(dV)⁴
wherein ‘dV’ refers to the applied voltage and ‘A1˜A4’ and ‘P1˜P4’ refer to parameter coefficients.

7. The method of claim 5, wherein the mathematical model comprises a quadratic polynomial with respect to a temperature of the capacitor.

8. The method of claim 7, wherein the quadratic polynomial comprises the formula:
T1·(T−Tn)+T2·(T−Tn)²
wherein ‘T’ refers to a temperature of the capacitor, ‘Tn’ refers to an ambient temperature around the capacitor, and ‘A1˜A4’ and ‘P1˜P4’ refer to parameter coefficients.

9. The method of claim 7, wherein the mathematical model includes the equations:
Cg=C1+C2
C1=CA·Area×[1+A1·dV+A2·(dV)²+A3·(dV)³+4·(dV)⁴]×[1+T1·(T−Tn)+T2·(T−Tn)²]
C2=CP·Peri×[1+P1·dV+P2·(dV)²+P3·(dv)³+P4·(dV)⁴]×[1+T1·(T−Tn)+T2·(T−Tn)²],
wherein ‘C1’ refers to a capacitance element for an area of the upper electrode of the capacitor, ‘C2’ refers to a capacitance element for a length of the upper electrode, ‘CA’ refers to a capacitance per unit area, ‘CP’ refers to a capacitance per unit length, ‘Area’ refers to the area of the upper electrode, ‘Peri’ refers to the length or perimeter of the upper electrode, ‘dV’ refers to the applied voltage, ‘T’ refers to a temperature of the capacitor, ‘Tn’ refers to an ambient temperature around the capacitor, and ‘A1˜A4’ and ‘P1˜P4’ refer to parameter coefficients.

10. The method of claim 9, wherein calculating the parameter coefficients uses an optimizing program.

11. The method of claim 1, further comprising:
simulating a system comprising the capacitance of the capacitor using the mathematical model and the calculated parameter coefficients.

12. The method of claim 2, further comprising:
simulating an integrated circuit comprising the high voltage depletion capacitor using the mathematical model and the calculated parameter coefficients.

13. The method of claim 11, wherein simulating the system includes supplying the mathematical model and the calculated parameter coefficients to an HSPICE simulator.

14. The method of claim 12, wherein simulating the system includes supplying the mathematical model and the calculated parameter coefficients to an HSPICE simulator.

15. A computer-readable medium comprising computer-executable instructions which, when executed in a computer, execute a set of instructions stored therein, the set of instructions comprising instructions for performing the method of claim 1.
